(19) United States
(12) Patent Application Publication
(10) Pub. No.: US 2010/0012949 A1
(43) Pub. Date: Jan. 21, 2010

(54) SUBSTRATE, IN PARTICULAR MADE OF SILICON CARBIDE, COATED WITH A THIN STOICHIOMETRIC FILM OF SILICON NITRIDE, FOR MAKING ELECTRONIC COMPONENTS, AND METHOD FOR OBTAINING SUCH A FILM

(75) Inventor: Patrick Soukiassian, Saint Remy Les Chevreuse (FR)

Correspondence Address: Nixon Peabody LLP, P.O. Box 60610, Palo Alto, CA, 94306, US

(73) Assignees: COMMISSARIAT A L'ENERGIE ATOMIQUE, PARIS (FR); UNIVERSITE PARIS SUD (PARIS XI), ORSAY (FR)

(21) Appl. No.: 11/988,284

(22) PCT Filed: Jul. 4, 2006
(86) PCT No.: PCT/EP2006/063858

§ 371 Date: Aug. 10, 2009

(30) Foreign Application Priority Data
Jul. 5, 2005 (FR) 05 52060

(51) Int. Cl. H01L 29/24; H01L 21/31

(52) U.S. Cl. 257/77; 438/770; 257/E29.104; 257/E21.24

(57) ABSTRACT

Substrate, in particular in silicon carbide, covered by a thin film of stoichiometric silicon nitride, for the manufacture of electronic components and method for obtaining said film.

To obtain the film on the substrate (1) in the presence of at least one nitrogen gas, the substrate is covered with a film (2) of a material that is permeable to said gas and the film of silicon nitride is capable of forming at the interface between the substrate and the film of the material. The invention applies for example to microelectronics.

### TECHNICAL FIELD

The present invention concerns a substrate, in particular in silicon carbide (SiC), covered by a thin film of stoichiometric silicon nitride, for the manufacture of electronic components and a method for obtaining said film.

It applies in particular to microelectronics.

### STATE OF THE PRIOR ART

Silicon is currently the semi-conductor material the most used in the electronics industry, principally due to its exceptional properties, particularly the insulating properties, of its native oxide, silicon dioxide (SiO₂). From this point of view, SiC is especially interesting since the passivation of its surface can be achieved by growth of SiO₂, under conditions similar to those of silicon.

Silicon carbide (SiC), a IV-IV semi-conductor compound, is therefore a very interesting material, which is particularly suited to devices and sensors of high power, high voltage, high frequency or high temperature and which may be monocrystalline (in cubic, hexagonal (there are more than 170 polytypes) or rhombohedral form), polycrystalline, amorphous or porous.

Its properties make it a material of choice in the industry of MOS (Metal Oxide Semiconductor) devices, gas sensors, particularly in fields where temperatures are high.

Recently, considerable progress has been made in the knowledge of surfaces of this material and interfaces of SiC, with insulators and metals. Important subjects for the success of electronic devices based on SiC, such as high performance MOS transistors and, in particular, those that are based on hexagonal (H) polytypes of this material, are surface passivation, which is linked to the oxidation of SiC, and insulating structures on SiC.

Independently of its exceptional qualities as a semi-conductor (factor of merit up to 1000 times greater than those of Si, GaAs and InP), SiC has the same native oxide (SiO₂) as silicon, an oxide whose insulating qualities remain at present unequalled.

However, conventional oxidation (direct oxidation) of SiC surfaces leads in general to the formation of silicon oxides containing carbon, which have mediocre electrical properties, and SiO₂/SiC interfaces that are not abrupt, the transition between SiC and SiO₂ occurring over several atomic layers, and do not improve said properties.

Moreover, it is known that during certain treatments undergone during the manufacture of electronic components based on technologies using silicon, dopants can migrate from one layer to another and lead to the formation of defects that alter the properties of the material.

Recently, methods enabling wafers of hexagonal SiC (4H polytype, which has the largest electronic gap) of very high quality, equivalent or superior to that of silicon, to be made, and practically without any defect, have been proposed.

In this respect, reference should be made to the article of Nakamura et al., Nature, 430, 1009, 2004.

These technological advances, which are without precedent in the class of semi-conductors with high electronic gap (comprising, in particular, apart from SiC, diamond, III-V nitrides and ZnO), open the way to numerous applications.

The recent development of such large size monocrystalline wafers (i.e. around 5 cm) is likely to stimulate considerable technological research in this field.

### DESCRIPTION OF THE INVENTION

The present invention forms part of this technological field and proposes a solution to one of the obligatory gateways for the success of the SiC option.

The aim of the present invention is to resolve the above mentioned problems and, in particular, the elimination of electronic states of interfaces, it also enables interfaces as abrupt as possible and exempt from defects to be obtained, as well as the elaboration of devices less sensitive to the migration of dopants during the manufacture of microelectronic devices.

The authors of the present invention have discovered in a surprising manner that the use of a very thin film of stoichiometric silicon nitride (Si₃N₄), formed at the surface of a silicon carbide substrate, enables the problems encountered up until now to be resolved.

The inventors have also discovered a method for preparing said film, having the property of limiting or blocking the diffusion of dopants and passivating the defects at insulator/semi-conductor interfaces (particularly SiO₂/Si).

More precisely, the subject of the present invention is firstly a substrate, particularly in silicon carbide, intended for the manufacture of electronic components, said substrate being characterised in that it is covered with a thin film of stoichiometric silicon nitride.

The invention further concerns a method for obtaining a film of stoichiometric silicon nitride on a substrate in the presence of at least one nitrogen gas, said method being characterised in that the substrate is covered with a film of a material that is permeable to said nitrogen gas and in that the film of stoichiometric silicon nitride is capable of forming at the interface between the substrate and the film of the material.

It is pointed out that the substrate is capable of receiving the material or favouring its formation.

According to a preferred embodiment of the method that is subject of the invention, the material is moreover capable of being oxidised.

Preferably, the material is silicon. Advantageously, said silicon is monocrystalline.

It is preferable that the film of the material has a thickness of between 0.5 nm and 20 nm.

Preferably, the substrate is silicon carbide. Advantageously, the silicon carbide is monocrystalline and has a β-SiC structure, in which case the face (100) is preferably used, or a α-SiC structure, in which case the face (0001) is preferably used.

For the deposition of the film of silicon, reference may be made to the document WO 01/39257 A, corresponding to U.S. Pat. No. 6,667,102 A.

Advantageously, the preparation of the surface of the substrate capable of receiving the monocrystalline silicon and/or favouring its formation comprises an auxiliary heating of the substrate to at least 1000° C., a substantially uniform auxiliary deposition of monocrystalline silicon on the surface of the heated substrate and at least one auxiliary annealing of the substrate after said auxiliary deposition, at least 650° C., the total time of the auxiliary annealing being at least 7 minutes.

According to the invention, it is preferable that the silicon is deposited in a substantially uniform manner on the surface of the substrate. Advantageously, the film of silicon has a cubic structure and its thickness ranges from 0.5 nm to 20 nm.

Preferably, the silicon is deposited on the substrate, said substrate being heated to around 650° C., the compound resulting from said deposition is then annealed at least 650° C., the total annealing time being at least 7 minutes, then cooled at a rate of at least 50° C./minute.

Before the above mentioned auxiliary heating, the preparation of the surface of the substrate comprises preferably a degassing of the substrate under ultra-high vacuum (10⁻¹⁰ Torr i.e. around 10⁻⁸ Pa) then at least one annealing of said substrate followed by a cooling of the substrate. It is preferable that the cooling is not too rapid in order to avoid thermal shocks.

According to a preferred embodiment of the invention, silicon is deposited from a surface of a sample of silicon, said surface being greater than the surface of the substrate, and the distance between said surfaces is between 2 cm and 3 cm.

The deposition of silicon may be followed by one or several annealings at temperatures between for example 700° C. and 1000° C. It is preferable to check the quality of the deposition, for example, by diffraction of low energy electrons (LEED) or high energy electrons (RHEED) or X-ray diffraction (XRD) or photoelectron diffraction (PED). Several annealings and depositions may thus be carried out until a film of silicon is obtained.

In a preferential manner, the silicon deposited is cubic, the lattice parameter of SiC being approximately equal to that of Si less 20%.

The silicon deposited preferentially has an atomic arrangement of 3×2 type to prepare a β-SiC(100) surface and of 4×3 type to prepare a α-SiC(0001) surface.

In the present invention, the nitrogen gas is preferably chosen among nitric oxide NO, NO₂, ammonia NH₃, nitrous oxide N₂O and atomic nitrogen. Advantageously, NO is used; in this case, it is preferable to eliminate all traces of oxide due to the oxynitriding, in order to obtain a stoichiometric film of silicon nitride (Si₃N₄); to do this, it is advantageous to employ a heat treatment such as an annealing of the surface, preferably at least 1000° C.

The exposure to NO may be carried out by various known methods, such as for example the exposure of the substrate to said gas through the intermediary of a tube or a gas input situated facing the substrate or not far from said substrate, in such a way that the enclosure in which the exposure to the gas is carried out contains the desired quantity of gas.

The exposure sufficiency may be controlled by spectrometry. Advantageously, synchrotron radiation-based photoemission spectroscopy is employed on the core levels Si 2p, C 1s, O 1s and N 1s.

According to a specific embodiment of the invention, the substrate is exposed to molecules of NO under vacuum. In this case, the exposure is preferably carried out under a regime from 100 langmuirs (around 10⁻² Pa·s) to 10000 langmuirs (around 1 Pa·s).

Preferentially, the exposure is carried out from a line of gas facing the surface of the substrate. The line of gas is placed at a distance D from the silicon carbide surface, D being preferably between 2 cm and 3 cm, so that the oxynitriding can take place in a homogeneous manner.

The exposure can take place independently at ambient temperature (from 10° C. to 30° C.) or up to 800 to 1000° C., in which case the substrate is heated by appropriate means, for example by Joule effect.

The above mentioned annealing may be carried out by appropriate means, for example by Joule effect; said means are preferably the same as those that may be employed during the exposure to NO.

Preferably, the annealing is carried out at a temperature between 800° C. and 1000° C., more specifically at 1000° C., the temperature from which it has been observed that only oxygen was eliminated. Advantageously, the cooling is carried out under vacuum or under inert atmosphere, preferably at a pressure ranging from 10⁻⁶ Pa to 10⁻⁵ Pa. In order to avoid a thermal shock, it is preferable that the rate of cooling does not exceed 50° C. per minute.

According to a specific embodiment of the invention, the steps of exposure and elimination of oxide (preferably by annealing) are carried out simultaneously or in a continuous manner.

The present invention further concerns a method for manufacturing an electronic component, in particular an MOS device, on a substrate, method in which a film of silicon nitride is formed on the substrate by the method that is the subject of the invention.

### BRIEF DESCRIPTION OF DRAWINGS

The present invention will be better understood by reading the description of the embodiments given hereafter, given purely by way of indication and in no way limiting, and by referring to the appended drawings, in which:

FIG. 1 schematically illustrates an installation enabling a film of stoichiometric silicon nitride Si₃N₄ according to the invention to be obtained, and

FIG. 2 is a schematic sectional view of a SiC substrate covered with such a film according to the invention.

### DETAILED DESCRIPTION OF SPECIFIC EMBODIMENTS

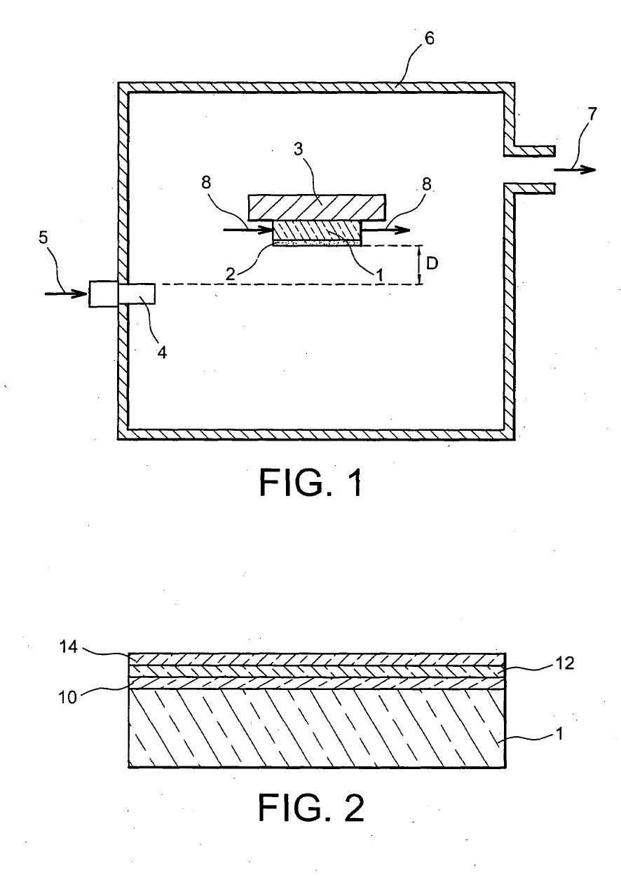

FIG. 1 schematically illustrates an installation enabling a stoichiometric film of Si₃N₄ according to the invention to be obtained.

References 1, 2 and 3 respectively represent a monocrystalline SiC substrate, a thin film of structured monocrystalline Si and a substrate support.

Reference 4 represents a line of NO gas. The arrow 5 symbolises the input of NO gas in the vacuum enclosure 6. The arrows 7 and 8 respectively symbolise means of pumping and means of heating the substrate 1, for example by Joule effect.

In the enclosure 6 takes place the formation of the film of Si₃N₄. The pumping means 7 enable the regime of exposure to molecules of NO to be obtained.

The substrate 1 covered with the film 2 of Si is mounted on the support 3.

The line of gas 4 supplies the enclosure 6 with NO molecules. It is positioned at a distance D from the surface of the substrate 1 in silicon carbide. This distance D is between 2 and 3 cm.

In a non limiting manner and according to an example of the invention, the substrate 1 of silicon carbide, covered with the thin film 2 of monocrystalline silicon, the thickness of which is for example at least 0.5 nm (which corresponds to several atomic planes of silicon), is exposed to molecules of NO, under vacuum, in the enclosure 6. This exposure under vacuum leads to an oxynitriding of the SiC substrate coated with the film of Si. The exposure is carried out from the line of gas 4 facing the surface of silicon carbide coated with the film of Si.

In a non limiting manner, the exposure is carried out at ambient temperature (10° C. to 30° C.), under a regime included, for example, between 100 langmuirs (around 10⁻² Pa·s) and 10000 langmuirs (around 1 Pa·s). It should be noted that this exposure can also take place at high temperature, up to a temperature of around 800° C. to 1000° C. In this case, the substrate is heated by the means 8.

The exposure is followed by an annealing at high temperature under ultra-high vacuum, for example at 1000° C.

As has been seen, the means of heating the substrate are used when an exposure to a temperature different from ambient temperature is chosen. For an exposure at ambient temperature, said means are therefore not used.

The means 8 of heating the substrate may also be used during annealing of the substrate under vacuum, carried out after the exposure leading to the oxynitriding of the silicon carbide surface.

The result of the application of the method according to the invention can be seen in FIG. 2: the substrate 1 is covered with a film 10 of stoichiometric Si₃N₄. A film 12 of non-stoichiometric Si₃N₄ covers this film 10 and the film 12 is covered by a film of residual silicon 14.

Among the remarkable properties of stoichiometric Si₃N₄, its ability to serve as diffusion barrier for dopants must be mentioned; this barrier makes it possible to prevent the diffusion of said dopants in the oxide film of SiO₂/Si interfaces; this property remains valid for SiC.

This advantageous property is important since the presence of said dopants in the oxide film leads to a very significant degradation of the performance of devices using such films such as, for example, MOS devices.

WO 01/39257A, corresponding to U.S. Pat. No. 6,667,102 A, discloses a method for manufacturing a film of silicon oxide, aiming to resolve a part of the aforementioned disadvantages, on a substrate in silicon carbide or in silicon, coated with a thin film of silicon having a 4×3 surface structure. This film may particularly and advantageously be formed on a 6H-SiC (0001) surface reconstructed for example 3×3, \sqrt{3}×\sqrt{3}, 6\sqrt{3}×6\sqrt{3} or 1×1.

In this case, it has been shown that abrupt SiO₂/SiC interfaces are obtained, the transition occurring practically over a few atomic layers between the substrate and the film of silicon formed.

After obtaining the film of stoichiometric Si₃N₄ by the method described above, the Si/SiC system may be “oxidised” by following for example the method disclosed in WO 01/39257 A.

A SiO₂/SiC interface is then obtained with, apart from a film of non-stoichiometric silicon nitride, a thin film of stoichiometric Si₃N₄ between the oxide SiO₂ and the SiC, which makes it possible to stop the diffusion of dopants in the film of oxide during the heat treatments used during the manufacture of electronic devices incorporating such films.

It is also possible to deposit a new film of Si in order to obtain a more or less thick film of SiO₂.

Another advantage of the thin film nitriding and oxynitriding is the role played by the two compounds of silicon in the passivation of defects at the SiO₂/SiC interfaces.

Indeed, the defects resulting from the oxidation of SiC lead to electronic states of interfaces, which have disastrous consequences on the mobility of the charge carriers, which alters in a very significant manner the frequency response of the micro-electronic devices in which they are incorporated.

From this point of view, the method of obtaining the film by nitriding according to the invention is very advantageous alone or in combination with that described in WO 01/39257 A.

Other examples of the present invention are given below.

The observation of the core levels involved in these other examples is carried out by synchrotron radiation-based photoemission spectroscopy.

The first example relates to the oxynitriding of a β-SiC(100) 3×2 structured surface and the formation of a sub-stoichiometric silicon nitride.

A surface (100) of cubic silicon carbide having the reconstruction 3×2 (β-SiC(100) 3×2) is prepared. As regards the preparation of such a surface, known to those skilled in the art, reference will be made for example to the article of Physical Review Letters, Soukiassian et al. 77, 2013 (1996), or to WO 01/39257 A.

The direct oxynitriding of the surface of the SiC is then carried out. To do this, the β-SiC(100) 3×2 surface, which has been prepared, is exposed to NO by evaporation under vacuum, from a line of gas facing the surface of the silicon carbide. The exposure is carried out at ambient temperature (around 10-30° C.), under a regime situated for example between 100 and 10000 langmuirs, in other words between around 10⁻² Pa·s and around 1 Pa·s.

This exposure can also be carried out at high temperature, up to a temperature of around 800° C. to 1000° C.

The interaction of nitric oxide NO with the surface, carried out at ambient temperature (around 10 to 30° C.), gives silicon oxynitriding products of Si—Oₓ—N_{y} type. Said oxynitrides grow underneath the surface, the Si atoms constituting the surface not being affected.

Thermal annealings around 650° C. lead to the formation of oxynitrides (Si—Oₓ—N_{y}) richer in nitrogen, this effect being already known for silicon. The annealings are carried out independently, under vacuum or under inert atmosphere.

They are carried out for example by passing a current in the sample and by controlling the temperature by means of a pyrometer. They can also be carried out by electronic bombardment, or instead by placing the sample in an oven. The result obtained with the sample based on SiC is similar to that obtained with Si.

It may be noted that an annealing at a temperature close to 1000° C. eliminates all of the oxygen and only leaves a single reaction product that is composed of a sub-stoichiometric silicon nitride of low thickness (ranging from an atomic layer to several nanometres), the presence of which is highlighted by observing the core electronic levels Si 2p and N 1s, whereas the absence of oxygen is highlighted by means of the core electronic level O 1s.

The carbon plane of the SiC, situated underneath the nitride, is not directly affected since it is the atoms of Si situated underneath the surface that are involved in the oxynitriding process. A similar situation has been observed in the interaction of oxygen with the SiC surface.

A second example relates to the oxynitriding of the β-SiC(100) 3×2 surface modified by a thin film of Si (of 3×2 structure) deposited and the formation of a stoichiometric nitride of Si (Si₃N₄).

To remedy the non-stoichiometric nature of the film of silicon nitride, silicon (around 2 to 3 atomic layers of Si) is deposited, in a substantially uniform manner, on the β-SiC(100) 3×2 surface of the substrate. As regards the protocol for depositing the film of silicon, reference should be made to WO 01/39257 A.

An oxynitriding of the SiC coated with the film of 3×2 Si is then carried out, in the same way as for the direct oxynitriding of the SiC not coated with a film of Si, as illustrated in the previous example. To do this, the silicon carbide coated with the film of 3×2 silicon Si thereby prepared is exposed to molecules of NO, by evaporation under vacuum from a line of gas facing the surface of the silicon carbide coated with the film of 3×2 Si.

The exposure is carried out at ambient temperature (10 to 30° C.), under a regime situated, for example, between 100 langmuirs and 10000 langmuirs, in other words between around 10⁻² Pa·s and around 1 Pa·s. It should be noted that this exposure also operates at high temperature, up to a temperature of around 800° C. to 1000° C.

As in the case of direct nitriding of SiC without 3×2 Si film, oxynitrides that are localised underneath the surface are again obtained, this time underneath the thin film of Si, above the first carbon plane of the SiC, at the interface of these two films.

However, an important difference appears: after an annealing at 1000° C. under vacuum, not only a sub-stoichiometric nitride of Si is obtained as above, but also a very thin film (between one and ten monoatomic layers) of Si₃N₄, constituted of stoichiometric Si nitride, which is also situated underneath the film of Si, above the carbon plane.

The presence of this film of stoichiometric Si₃N₄ is highlighted by observing the core electronic levels Si 2p and N 1s, whereas the absence of oxygen is highlighted by means of the core electronic level O 1s.

In this case, the film of Si₃N₄ is very thin (between one and ten monoatomic layers) but its thickness is sufficient to block the diffusion of dopants, without altering the qualities of the SiO₂ insulating film that can be grown on the film of Si after having obtained the film of stoichiometric Si₃N₄.

A third example relates to the oxynitriding of the α-SiC(0001) 3×3 surface, on which a film of Si (several atomic layers in 4×3 formation) has been deposited, and the formation of stoichiometric silicon nitride (Si₃N₄) .

The oxynitriding is also carried out on a substrate of monocrystalline silicon carbide, having a α-SiC (0001) 3×3 structured surface. The oxynitriding experimental method described above is applied to the hexagonal silicon carbide coated with a film of pre-deposited Si, forming a 4×3 cubic Si structure. To prepare such a surface of SiC coated with 4×3 Si, one of the known methods is used, for example the method disclosed in WO 01/39257 A.

To obtain a film of Si₃N₄, an oxynitriding of the SiC coated with 4×3 Si is carried out. To this end, the silicon carbide, coated with the film of 4×3 Si silicon thereby prepared, is exposed to molecules of NO by evaporation under vacuum, from a line of gas facing the surface of the coated silicon carbide.

The exposure is carried out at ambient temperature (around 10 to 30° C.), under a regime situated, for example, between 100 and 10000 langmuirs, in other words between around 10⁻² Pa·s and around 1 Pa·s. It should be noted that this exposure operates also at high temperature, up to a temperature of around 800° C. to 1000° C.

As in the case of the β-SiC(100) 3×2 surface of the silicon carbide coated with the film of 3×2 Si, oxynitrides are again obtained that are localised underneath the surface, underneath the thin film of Si, above the first carbon plane of the SiC.

After an annealing at 1000° C., not only a sub-stoichiometric nitride of Si is obtained as previously, but also a very thin film (between one and ten monoatomic layers) of Si₃N₄, constituted of stoichiometric Si nitride, which is also situated underneath the film of Si, above the carbon plane.

The presence of this film of Si₃N₄ is highlighted by observing the core electronic levels Si 2p and N 1s, whereas the absence of oxygen is highlighted by means of the core electronic level O 1s.

Thus, the presence of the thin film (between one and ten monoatomic layers) of stoichiometric nitride Si₃N₄ formed underneath the surface, near to the carbon plane, confirms the usefulness of the method of oxynitriding the substrate in the presence of a film of monocrystalline silicon.

1. Substrate (1), in particular in silicon carbide, intended for the manufacture of electronic components, said substrate being characterised in that it is covered with a thin film (10) of stoichiometric silicon nitride.

2. Method for preparing a film of silicon nitride on a silicon carbide substrate (1) covered with a film (2) of a material, said method being characterised in that the substrate (1) is exposed to at least one nitrogen gas and in that the material is permeable to said nitrogen gas.

3. Method according to claim 2, in which the material is moreover capable of being oxidised.

4. Method according to claim 3, in which the material is silicon.

5. Method according to claim 2, in which the film (2) of material has a thickness of between 0.5 nm and 20 nm.

6. (canceled)

7. Method according to claim 2, in which the substrate (1) is monocrystalline silicon carbide of β-SiC or α-SiC structure.

8. Method according to claim 6, in which the face covered with the material is the face (0001) in the case of the substrate of α-SiC silicon carbide, and the face (100) in the case of the substrate of β-SiC silicon carbide.

9. Method according to claim 2, in which the quality of the exposure to nitrogen gas is controlled by means of spectrometric methods.

10. Method according to claim 2, in which the nitrogen gas is chosen among nitric oxide NO, NO₂, ammonia NH₃, nitrous oxide N₂O and atomic nitrogen.

11. Method according to claim 2, in which the nitrogen gas is nitric oxide and in which the method comprises a step of eliminating an oxide formed during the exposure to the nitrogen gas.

12. Method according to claim 10, in which the oxide formed is eliminated by a heat treatment.

13. Method according to claim 11, in which the oxide formed is eliminated by an annealing at least 1000° C.

14. Method according to claim 10, in which the steps of exposure and elimination are carried out simultaneously.

15. (canceled)

16. Method for passivating a silicon carbide substrate, characterised in that it comprises a step of preparing a film (10) of silicon nitride by the method according to claim 2 and a step of oxidising the surface of the material.

17. Method for manufacturing an electronic component, particularly an MOS device, on a substrate, method in which a film of silicon nitride is formed on the substrate by the method according to claim 2.
